(19) United States
(12) Patent Application Publication
(10) Pub. No.: US 2025/0015084 A1
(43) Pub. Date: Jan. 9, 2025

(54) SEMICONDUCTOR DEVICE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Yongliang Li, Beijing (CN); Fei Zhao, Beijing (CN)

(21) Appl. No.: 18/763,440

(22) Filed: Jul. 3, 2024

(30) Foreign Application Priority Data
Jul. 6, 2023 (CN) 202310832147.6

(51) Int. Cl. H01L 27/092; H01L 21/225; H01L 21/762; H01L 29/06; H01L 29/161; H01L 29/24; H01L 29/417; H01L 29/423; H01L 29/66; H01L 29/775; H01L 29/786

(52) U.S. Cl. CPC H01L 27/0922; H01L 21/225; H01L 29/161; H01L 29/24; H01L 21/762; H01L 29/0673; H01L 29/41775; H01L 29/42392; H01L 29/66439; H01L 29/775; H01L 29/78696

(57) ABSTRACT

A semiconductor device and a method for manufacturing the same. The semiconductor device comprises an n-channel GAA transistor and a p-channel GAA transistor, which are spaced apart. Each of the n-channel GAA transistor and the p-channel GAA transistor comprises a source, a drain, and at least one nanostructure layer located between the source and the drain. The p-channel GAA transistor further comprises a gate stack structure and a gate sidewall. In the p-channel GAA transistor, the at least one nanostructure layer comprises a channel portion that is covered by the gate stack structure and a connecting portion that is covered by the gate sidewall, and germanium content in the channel portion is greater than germanium content in the connecting portion and is greater than germanium content in the at least one nanostructure layer of the n-channel GAA transistor.

This application claims priority to Chinese Patent Application No. 202310832147.6, titled “SEMICONDUCTOR DEVICE AND METHOD FOR MANUFACTURING THE SAME”, filed on Jul. 6, 2023, with the China National Intellectual Property Administration, which is incorporated herein by reference in its entirety.

### FIELD

The present disclosure relates to the technical field of semiconductors, and in particular to a semiconductor device and a method for manufacturing the semiconductor device.

### BACKGROUND

In gate-all-around (GAA) transistors, a gate stack of is not only formed on a top surface and sidewalls of a channel, but also formed beneath the channel. Thereby, the GAA transistors have a better gate-control capability on the channel in comparison with planar transistors and fin field-effect transistors.

In corresponding complementary metal-oxide-semiconductor (CMOS) devices, channels of n-channel metal-oxide-semiconductor (NMOS) GAA transistors are generally fabricated from strained silicon, germanium silicon with low germanium content, or III-V compound semiconductors, while channels of p-channel metal-oxide-semiconductor (PMOS) GAA transistors are generally fabricated from high-mobility materials such as germanium silicon. Thereby, a difference in carrier mobility between the NMOS GAA transistors and the PMOS GAA transistors are small enough to ensure that the transistors of both types have good conductivity.

In conventional technology, it is difficult to manufacture the NMOS GAA transistors and PMOS GAA transistors having different channel materials, and thus it is difficult to improve performances of the CMOS devices.

### SUMMARY

A semiconductor device and a method for manufacturing the semiconductor device are provided according to embodiments of the present disclosure. N-channel metal-oxide-semiconductor (NMOS) gate-all-around (GAA) transistors and p-channel metal-oxide-semiconductor (PMOS) GAA transistors having different channel materials can be manufactured, and performances of corresponding complementary metal-oxide-semiconductor (CMOS) devices can be improved.

In a first aspect, a semiconductor device is provided according to an embodiment of the present disclosure. The semiconductor device comprises an n-channel GAA transistor and a p-channel GAA transistor, which are spaced apart. Each of the n-channel GAA transistor and the p-channel GAA transistor comprises a source, a drain, and at least one nanostructure layer located between the source and the drain. The p-channel GAA transistor further comprises a gate stack structure and a gate sidewall. In the p-channel GAA transistor, the at least one nanostructure layer comprises a channel portion that is covered by the gate stack structure and a connecting portion that is covered by the gate sidewall, and germanium content in the channel portion is greater than germanium content in the connecting portion and is greater than germanium content in the at least one nanostructure layer of the n-channel GAA transistor.

In the above structure, the at least one nanostructure layer of the p-channel GAA transistor is located between the source and the drain and comprises the channel portion covered by the gate stack structure and the connecting portion covered by the gate sidewall. Moreover, the germanium content in the channel portion is greater than that in the at least one nanostructure layer of the n-channel GAA transistor. Carrier mobility of germanium-based semiconductor materials, such as SiGe or Ge, is higher than that of semiconductor materials, such as Si, of nanostructures in conventional n-channel GAA transistors. Hence, since both transistors are of the GAA type, the carrier mobility of the channel in the n-channel GAA transistor may be improved to a degree exceeding that of the channel in the p-channel GAA transistor. In such case, the germanium content of the channel portion in the p-channel GAA transistor may be configured higher that of the nanostructure layer in the n-channel GAA transistor to reduce a difference in carrier mobility between the channels of the two GAA transistors. In addition, lower germanium content of the nanostructure layer in the n-channel GAA transistor can avoid occurrence of poor interfacial states, high source-drain contact resistance, and the like. Thereby, both n-channel GAA transistor and the p-channel GAA transistor can have good electrical performances.

Moreover, semiconductor materials having a lower germanium content, such as Si, have a wider bandgap that those having higher germanium content. Hence, lower germanium content provides stronger constraint on carriers. In the p-channel GAA transistor, the connecting portion having a lower germanium content, which is located between the channel portion having a higher germanium content and the source or the drain, is capable to strengthen the constraint in such region. Hence, leakage is reduced, and the electrical performances of the p-channel GAA transistor are further improved.

In the second aspect, a method for manufacturing a semiconductor device is provided according to an embodiment of the present disclosure. The method comprises a following step. An n-channel GAA transistor and a p-channel GAA transistor, which are spaced apart, are provided. Each of the n-channel GAA transistor and the p-channel GAA transistor comprises a source, a drain, and at least one nanostructure layer located between the source and the drain. The p-channel GAA transistor further comprises a gate stack structure and a gate sidewall. In the p-channel GAA transistor, the at least one nanostructure layer comprises a channel portion that is covered by the gate stack structure and a connecting portion that is covered by the gate sidewall, and germanium content in the channel portion is greater than germanium content in the connecting portion and is greater than germanium content in the at least one nanostructure layer of the n-channel GAA transistor.

In an embodiment, providing the n-channel GAA transistor and the p-channel GAA transistor comprises following steps. A first structure and a second structure, which are spaced apart, are formed on a surface of a semiconductor substrate. Each of the first structure and the second structure comprises at least one suspended channel layer and a gate sidewall, which is astride the at least one suspended channel layer at two ends of the at least one suspended channel layer along a length direction. The second structure further comprises germanium-containing layers located on two sides of each of the at least one suspended channel layer along a thickness direction. A germanium content in the germanium-containing layers is greater than germanium content in each of the at least one suspended channel layer. A portion of the germanium-containing layers and the at least one suspended channel layer in the second structure is oxidized to segregate germanium. The portion is exposed from a first mask layer and the gate sidewall. The first mask layer shields the first structure. Afterwards, the n-channel GAA transistor is formed based on the first structure, and the p-channel GAA transistor is formed based on the second structure.

Beneficial effects of the method may refer to those of the semiconductor device in the first aspect and would not be repeated here.

### BRIEF DESCRIPTION OF THE DRAWINGS

Hereinafter drawings to be applied in embodiments of the present disclosure or in conventional technology are briefly described, in order to clarify illustration of technical solutions according to embodiments of the present disclosure or in conventional technology. Apparently, the drawings in the following descriptions are only some embodiments of the present disclosure, and other drawings may be obtained by those skilled in the art based on the provided drawings without exerting creative efforts.

FIGS. 1 to 9 are schematic structural diagrams in a process of manufacturing semiconductor devices of two configurations according to embodiments of the present disclosure.

FIG. 10 to 20 are schematic structural diagrams in a process of manufacturing a semiconductor device according to an embodiment of the present disclosure.

FIGS. 21 and 22 are schematic structural diagrams in a process of manufacturing semiconductor devices of two configurations according to embodiments of the present disclosure.

Reference numerals:

| | |
|---|---|
| 11: semiconductor substrate; | 12: first fin structure; |
| 13: second fin structure; | 14: period of stacked layers; |
| 15: sacrificial layer; | 16: first semiconductor layer; |
| 17: second semiconductor layer; | 18: germanium-containing material |
| | layer; |
| 19: isolation layer; | 20: shallow trench isolation; |
| 21: sacrificial gate; | 22: gate sidewall; |
| 23: recess; | 24: inner sidewall; |
| 25: source; | 26: drain; |
| 27: dielectric isolation layer; | 28: interlayer dielectric layer; |
| 29: second mask layer; | 30: suspended channel layer; |
| 31: germanium-containing layer; | 32: first structure; |
| 33: second structure; | 34: first mask layer; |
| 35: nanostructure; | 36: channel portion; |
| 37: connecting portion; | 38: gate stack structure. |

### DETAILED DESCRIPTION OF EMBODIMENTS

Hereinafter embodiments of the present disclosure will be described with reference to the drawings. The description is only exemplary and is not intended for limiting the scope of the present disclosure. Herein description on well-known structures and techniques are omitted to avoid unnecessarily confusion on concepts of the present disclosure.

Various structural schematic diagrams for embodiments of the present disclosure are shown in the drawings. The drawings are not drawn to scale, and some details may be enlarged while some details may have been omitted for conciseness. Shapes, relative dimensions, and relative positions of various regions and layers shown in the figures are only exemplary. In practice, there may be deviations due to manufacturing tolerances or technical limitations. Those skilled in the art may design a region or a layer having a different shape, dimension, or position according to an actual requirement.

Herein when a layer/element is defined as being “on” another layer/element, it may be disposed directly on the other layer/element, or there may be intervening layers/elements between the two. In addition, in a case that one layer/element is “over/above” another layer/element in one orientation, such layer/element may be “under/beneath” the other layer/element in a reversed orientation. In order to clarify addressed technical issues, technical solutions, and beneficial effects of the present disclosure, the present disclosure will be further described in detail below with reference to the drawings and embodiments. Specific embodiments described herein are only intended for explaining the present disclosure rather than limiting the present disclosure.

In addition, terms such as “first” and “second” are for descriptive purposes and shall not be construed as indicating explicitly or implicitly relative importance among or a quantity of concerning technical features. That is, a subject modified by “first” or “second” may indicate one or more of such subjects. Unless explicitly indicated otherwise, herein the term “multiple” refers to two or more, and the term “some” refers to one or more.

Unless explicitly stated or limited otherwise, herein the terms “mounted”, “connected”, and “interconnected” shall be interpreted in a broad sense. For example, they may refer to fixed connection, detachable connection, or integral connection, may refer to mechanical connection or electrical connection, may refer to direct connection or indirect connection via an intermediate medium, and may refer to internal connection between two elements or interaction between two elements. Those skilled in the art may appreciate specific meaning of the above terms according to specific context.

In gate-all-around (GAA) transistors, a gate stack of is not only formed on a top surface and sidewalls of a channel, but also formed beneath the channel. Thereby, the GAA transistors have a better gate-control capability on the channel in comparison with planar transistors and fin field-effect transistors. Performances of a complementary metal-oxide-semiconductor (CMOS) device can be improved when both the n-channel metal-oxide-semiconductor (NMOS) transistor and the p-channel metal-oxide-semiconductor (PMOS) transistor in the CMOS device adopt a GAA structure.

Generally, a channel in the GAA transistor is grown along crystal orientation [100]. Such channel behaves well when transmitting electrons but not so well when transmitting of holes. Since majority carriers of the NMOS transistor are electrons while those of the PMOS transistor are holes, the GAA transistor of which the channel is grown along crystal orientation [100] behaves well in electron mobility of the NMOS transistor but not so well in hole mobility of the PMOS transistor. Hence, performances of the CMOS device based on such GAA transistors are not satisfactory. Since materials such as germanium silicon can provide higher carrier mobility, the channel comprising at least one nanostructure may be fabricated from such high-mobility materials improve the hole mobility in the PMOS transistor. These high-mobility materials when fabricating the channel in the NMOS transistor may induce problems such as poor interfacial states and high source-drain contact resistance. Hence, in conventional techniques, the channel of the PMOS transistor is generally fabricated based on high-mobility materials such as germanium silicon, while the channel of the NMOS transistor is generally fabricated from strained silicon, germanium silicon with lower germanium content, or III-V compound semiconductors. When both the NMOS transistor and the PMOS transistor in the CMOS device are GAA transistors, the carrier mobility of the channel in the NMOS transistor may exceed that of the channel in the PMOS transistor. In such case, the channel of the PMOS transistor which is fabricated based on the high-mobility material may be tuned to reduce a difference between the carrier mobilities of the two channels. Thereby, both transistors can have good electrical performances.

In practice, when manufacturing the CMOS device, the channel of the NMOS transistor and sacrificial layer(s) for the PMOS transistor may be made of the same material, and the channel of the PMOS transistor and sacrificial layer(s) for the NMOS transistor may be made of the same material. In such case, when Si sacrificial layer(s) are removed to release the channel of the PMOS transistor, low etching selectivity for the SiGe channel in the PMOS transistor results in poor morphology quality of the SiGe channel. In addition, one of the NMOS transistor and the PMOS transistor may have a thicker channel than the other, and it is difficult to fill gaps between adjacent nanostructures in the channel and between the nanostructures and a substrate in such transistor with the gate stack. Hence, performances of the transistor having the thicker channel are reduced. That is, the CMOS device having different channel materials for the NMOS transistor and the PMOS transistor is difficult to be manufactured through conventional solutions.

A semiconductor device and a method for manufacturing the semiconductor device are provided according to embodiments of the present disclosure. In the semiconductor device, germanium content in a channel portion of the p-channel GAA transistor is greater than germanium content in at least one nanostructure layer in the n-channel GAA transistor, so that both the n-channel GAA transistor and the p-channel GAA transistor have good conductivity. The germanium content in the channel portion is also greater than germanium content in a connecting portion of the p-channel GAA transistor, which reduces leakage.

Reference is made to subfigures (1) and (2) of FIGS. 20 to 22. In an embodiment, the semiconductor device comprises a n-channel GAA transistor and a p-channel GAA transistor that are spaced apart. The n-channel GAA transistor and the p-channel GAA transistor each comprises an active structure, and the active structure comprises a source 25, a drain 26, and at least one nanostructure layer 35 located between the source 25 and the drain 26. As shown in subfigures (1) and (2) of FIG. 22, the at least one nanostructure layer 35 in the p-channel GAA transistor comprises a channel portion 36 covered by a gate stack structure 38 of the p-channel GAA transistor and a connecting portion 37 covered by a gate sidewall 22 of the p-channel GAA transistor. Herein the germanium content in the channel portion 36 is greater than the germanium content in the connecting portion 37 and is greater than the germanium content in the at least one nanostructure layer 35 in the n-channel GAA transistor.

Reference is further made to subfigures (1) and (2) of FIGS. 20 to 22. In an embodiment, the semiconductor device may further comprise a semiconductor substrate 11. As shown in FIG. 20, the n-channel GAA transistor and the p-channel GAA transistor may be arranged on the semiconductor substrate 11 and spaced apart along a direction parallel to a surface of the semiconductor substrate 11. Alternatively, as shown in subfigure (2) of FIG. 22, the n-channel GAA transistor(s) and the p-channel GAA transistor(s) may be arranged on the semiconductor substrate 11 and spaced apart along a thickness direction. Herein the thickness direction refers to a direction perpendicular to a surface of the semiconductor substrate 11 facing the two transistors, i.e., a direction along which the nanostructure layers 35 are sequentially arranged.

The semiconductor substrate may be, for example, a silicon substrate, a silicon germanium substrate, a germanium substrate, or a silicon-on-insulator substrate. The semiconductor substrate alone may refer to a substrate on which no additional structure is provided.

Alternatively, the semiconductor substrate may refer to a substrate on which one or more structures has been formed. The structure(s) formed on the semiconductor substrate may be determined according to an actual application scenario and are not specifically limited herein. For example, the semiconductor device is to be manufactured in the second bottommost layer or even a higher layer of an integrated circuit, the semiconductor substrate may comprise a semiconductor base, one or more device layers located on the semiconductor base and below the semiconductor device, and interlayer dielectric layer(s) isolating devices in different device layers.

In addition, when the n-channel GAA transistor and the p-channel GAA transistor are spaced apart the thickness direction of the semiconductor substrate, the n-channel GAA transistor and the p-channel GAA transistor form a complementary field-effect transistor (CFET) device. In the CFET device, the n-channel GAA transistor may be located below the p-channel GAA transistor, or as shown in subfigure (2) of FIG. 22, the p-channel GAA transistor may be located below the n-channel GAA transistor. The semiconductor device may comprise a dielectric isolation layer 27 located between the n-channel GAA transistor and the p-channel GAA transistor. The dielectric isolation layer 27 may be located between the source 25 plus the drain 26 in the n-channel GAA transistor and the source 25 plus the drain 26 in the p-channel GAA transistor. A material of the dielectric isolation layer 27 may be insulating, for example, may be silicon oxide, silicon nitride, or silicon oxynitride. A thickness of the dielectric isolation layer 27 is not specifically limited herein.

The n-channel GAA transistor and p-channel GAA transistor each comprise the active structure, a gate stack structure, and a gate sidewall. In the n-channel GAA transistor, the gate sidewall is formed at least on two sides of the gate stack structure along a length direction, the gate stack structure surrounds each nanostructure layer, and the gate sidewall is astride two edge portions (e.g., two ends) of the nanostructure layer along the length direction. Herein the length direction refers to a direction pointing from a source to a corresponding drain, or vice versa), and the length direction is generally parallel to the surface of the substrate 11 and hence perpendicular to the thickness direction as defined above. In an embodiment, the gate stack structure in the n-channel GAA transistor comprises at least a gate dielectric layer surrounding each nanostructure layer and a gate located on the gate dielectric layer. In the n-channel GAA transistor, the nanostructure layer(s) comprises a portion covered by the gate sidewall and another portion covered by the gate stack structure, and the two portions are formed in a same process and are identical or substantially identical in material.

Reference is made to subfigure (1) of FIG. 22. In the p-channel GAA transistor, the gate sidewall 22 is formed at least on two sides of the gate stack structure 38 along the length direction, the gate stack structure 38 surrounds the channel portion 36 of the nanostructure layer(s) 35, and the gate sidewall 22 is astride the connecting portion 37 of the nanostructure layer(s) 35. In an embodiment, the gate stack structure 38 in the p-channel GAA transistor comprises a gate dielectric layer at least surrounding each nanostructure layer 35 and a gate located on the gate dielectric layer.

The sources and the drains in the n-channel GAA transistor and the p-channel GAA transistor may be made of semiconductor materials such as silicon, silicon germanium, or germanium. The gate sidewalls in the n-channel GAA transistor and the p-channel GAA transistor may be made of insulating materials such as silicon oxide, silicon nitride, or silicon oxynitride. The gate dielectric layers in the n-channel GAA transistor and the p-channel GAA transistor may be made of a high-x material such as HfO₂, ZrO₂, TiO₂, or Al₂O₃. The gates in the n-channel GAA transistor and the p-channel GAA transistor may be made of a conductive material such as TiN, TaN, or TiSiN.

A material of the nanostructure layer(s) in the n-channel GAA transistor and a material of the channel portion and the connecting portion of the nanostructure(s) in the p-channel GAA transistor may be determined according to an actual application scenario. They can be appropriately configured as long as the germanium content in the channel portion is greater than both that in the connecting portion and that in the nanostructure layer(s) of the n-channel GAA transistor.

In an embodiment, the germanium content in the channel portion may be greater than or equal to 10% and less than or equal to 60%. For example, the germanium content in the channel portion may be 10%, 20%, 30%, 40%, 50%, 60%, or the like. The germanium content in the channel portion within such range is capable to ensure adequate improvement on the carrier mobility of the nanostructure layer(s) in the p-channel GAA transistor and a small difference in carrier mobility between the nanostructure layer(s) in the n-channel GAA transistor and the nanostructure layer(s) in the p-channel GAA transistor. In practice, the germanium content in the channel portion may be configured higher than the germanium content in the connecting portion through oxidation for segregation. The germanium content in the channel portion within such range is also capable to prevent excessively high germanium content from bringing difficulties to fabrication of the nanostructure layer(s) in the p-channel GAA transistor. Hence, it is convenient to manufacture the semiconductor device.

In an embodiment, the channel portion may be made of any semiconductor material containing germanium. For example, a material of the channel portion may be germanium silicon, silicon germanium gallium, silicon germanium indium, or the like.

In an embodiment, the germanium content in the nanostructure layer(s) in the n-channel GAA transistor and/or the connecting portion in the p-channel GAA transistor may be equal to zero. In such case, the nanostructure layer(s) in the n-channel GAA transistor and/or the connecting portion in the p-channel GAA transistor may be made of, for example, silicon, silicon carbide, carbon silicon arsenic, or carbon silicon antimony.

In another embodiment, the germanium content in the nanostructure layer(s) in the n-channel GAA transistor and/or the connecting portion in the p-channel GAA transistor may be low but not zero. A specific value of the low germanium content may be determined according to the germanium content in the channel portion, as long as it is applicable to the semiconductor device provided herein. The low germanium content may be implemented through a material such as germanium silicon, silicon germanium gallium, or silicon germanium indium.

For example, the germanium content in the nanostructure layer(s) in the n-channel GAA transistor and/or the connecting portion in the p-channel GAA transistor is made of germanium silicon in which the germanium content is less than 10%.

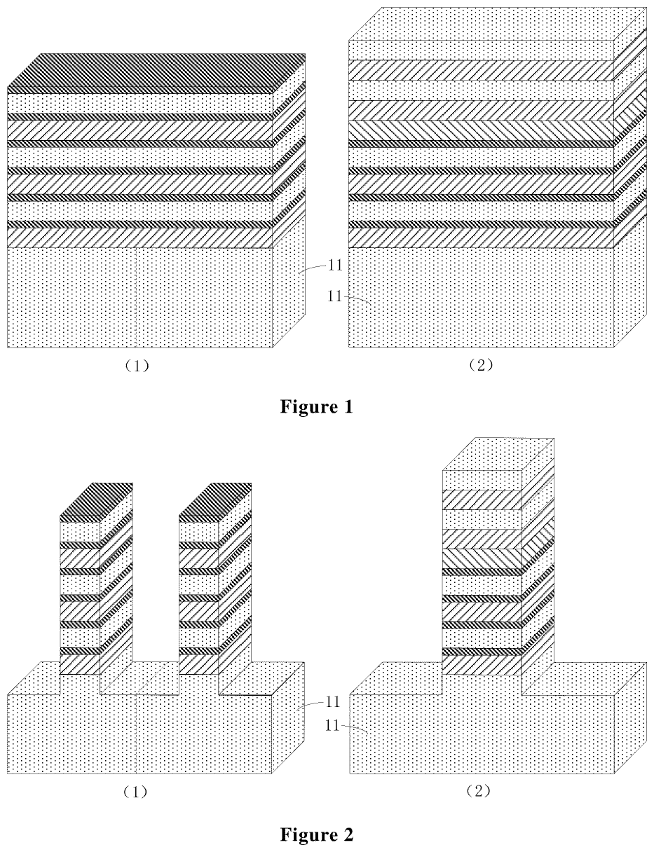

Reference is made to FIG. 20 and subfigure (1) of FIG. 22, in which the n-channel GAA transistor and the p-channel GAA transistor are spaced apart along the direction parallel to the surface of the semiconductor substrate 11. The nanostructure layer 35 in the n-channel GAA transistor, the connecting portion 37, and the channel portion 36 may be identical in material except for the germanium content. Reference is made to subfigures (1) of FIGS. 1 through 9 and to FIGS. 10 through 20. The nanostructure layers 35 in the n-channel GAA transistor and the p-channel GAA transistor may be fabricated from the same suspended channel layers 30. Hence, manufacture of the semiconductor device is simplified.

Reference is made to subfigure (2) of FIG. 22, in which that the n-channel GAA transistor and the p-channel GAA transistor are spaced apart along the thickness direction of the semiconductor substrate 11. The material of the nanostructure layer 35 in the n-channel GAA transistor may be different from the material of the nanostructure layer 35 in the p-channel GAA transistor in at least one element besides the germanium content. For example, the material of the nanostructure layer 35 in the n-channel GAA transistor may be silicon carbide, the material of the channel portion 36 is germanium silicon, and the material of the connecting portion 37 is silicon. Alternatively, in such case, the material of the nanostructure layer 35 in the n-channel GAA transistor, the material of the connecting portion 37, and the material of the channel portion 36 may be identical except in the germanium content. For example, the material of the nanostructure layer 35 in the n-channel GAA transistor is silicon, the material of the channel portion 36 is germanium silicon, and the material of the connecting portion 37 is silicon.

Reference is made to subfigures (1) and (2) in FIG. 22. In the p-channel GAA transistor, the at least one nanostructure layer 35 is located between the source 25 and the drain 26 in the p-channel GAA transistor. In addition, the at least one nanostructure layer 35 in the p-channel GAA transistor comprise the channel portion 36 covered by the gate stack structure 38 and the connecting portion 37 covered by the gate sidewall 22. Moreover, the germanium content in the channel portion 36 is greater than that in the at least one nanostructure layer 35 of the n-channel GAA transistor. Carrier mobility of germanium-based semiconductor materials, such as SiGe or Ge, is higher than that of semiconductor materials, such as Si, of nanostructures in conventional n-channel GAA transistors. Hence, since both transistors are of the GAA type, the carrier mobility of the channel in the n-channel GAA transistor may be improved to a degree exceeding that of the channel in the p-channel GAA transistor. In such case, the germanium content of the channel portion 36 in the p-channel GAA transistor may be configured higher that of the nanostructure layer 35 in the n-channel GAA transistor to reduce a difference in carrier mobility between the channels of the two GAA transistors. In addition, lower germanium content of the nanostructure layer 35 in the n-channel GAA transistor can avoid occurrence of poor interfacial states, high source-drain contact resistance, and the like. Thereby, both n-channel GAA transistor and the p-channel GAA transistor can have good electrical performances. Moreover, semiconductor materials having a lower germanium content, such as Si, have a wider bandgap that those having higher germanium content. Hence, lower germanium content provides stronger constraint on carriers. In the p-channel GAA transistor, the connecting portion 37 having a lower germanium content, which is located between the channel portion 36 having a higher germanium content and the source 25 or the drain 26, is capable to strengthen the constraint in such region. Hence, leakage is reduced, and the electrical performances of the p-channel GAA transistor are further improved.

Reference is made to subfigures (1) and (2) of FIG. 22. In an embodiment, the p-channel GAA transistor comprises inner sidewalls 24 located between the source 25 and the gate stack structure 38 and between the drain 26 and the gate stack structure 38. In the p-channel GAA transistor, a length of the inner sidewall 24 is uniform throughout the thickness direction, or a length of a portion of the inner sidewall 24 is greater than another portion of the inner sidewall 24 throughout the thickness direction. Herein the length of the inner sidewall 24 refers to a dimension of the inner sidewall 24 along the length direction.

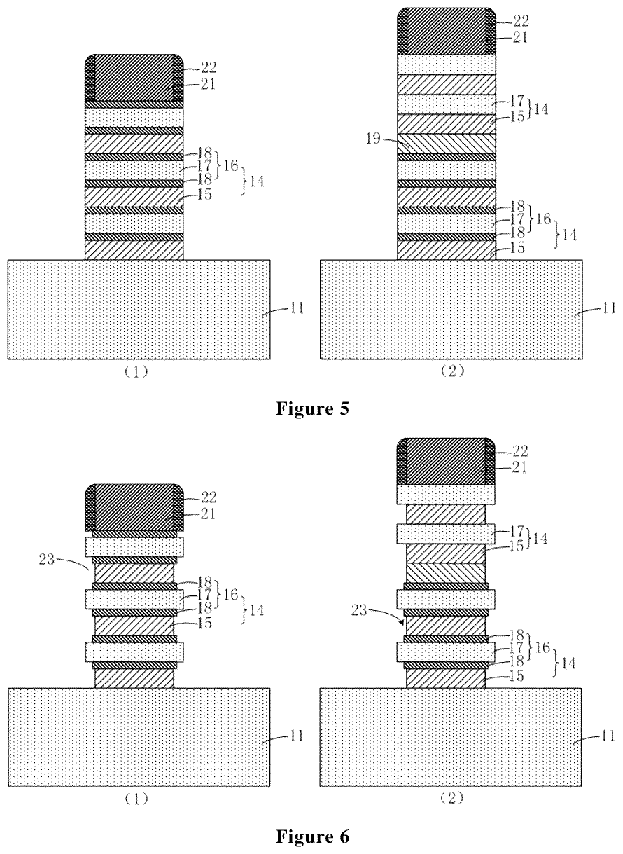

Reference is made to subfigures (1) and (2) of FIG. 5 and FIG. 6. In practice, edge portions (e.g., ends) of germanium-containing layers 18 and sacrificial layer(s) 15 are etched to form recesses 23 during manufacture. In a case that a rate of etching the sacrificial layer(s) 15 is greater than that of etching the germanium-containing layers 18, the length of the portion of the inner sidewall 24 would be greater than the other portions of the inner sidewall 24 throughout the thickness direction. In such case, the portion of the inner sidewall 24 protrudes toward the gate stack structure 38 and occupies a space formed through etching the corresponding sacrificial layer 15. In a case that the rate of etching the sacrificial layer(s) 15 is substantially identical to that of etching the germanium-containing layers 18, the length of the inner sidewall 24 is uniform throughout the thickness direction.

The length of the inner sidewall in the p-channel GAA transistor throughout the thickness direction may be determined according to a material of the sacrificial layer(s), a material of the germanium-containing layers, and actual processing in manufacture. The length is not specifically limited herein.

When a length of the gate stack structure in the p-channel GAA transistor is constant, the portion of the inner sidewall protruding towards the gate stack structure is capable to increase a space between the source (or the drain) and the gate stack structure. Thereby, parasitic capacitance between the source/drain and the gate stack structure is reduced, which improves performances of the p-channel GAA transistor.

Reference is made to subfigure (2) of FIG. 22. In an embodiment, the n-channel GAA transistor comprises an inner sidewall 24 located between the source 25 and the gate stack structure 38 and between the drain 26 and the gate stack structure 38. In the n-channel GAA transistor, a length of the inner sidewall 24 is uniform throughout the thickness direction, or the length of a portion of the inner sidewall 24 is greater than the length of other portions of the inner sidewall throughout the thickness direction. Herein the length of the inner sidewall 24 refers to a dimension of the inner sidewall 24 along the length direction.

In a case that the n-channel GAA transistor and the p-channel GAA transistor are spaced apart along the direction parallel to the surface of the semiconductor substrate, configuration of the inner sidewall of the n-channel GAA transistor may refer to that of the aforementioned inner sidewall of the p-channel GAA transistor.

Reference is made to subfigure (2) of FIG. 22, in which the n-channel GAA transistor and the p-channel GAA transistor are spaced apart along the thickness direction of the semiconductor substrate 11. When manufacturing the nanostructure layer in the n-channel GAA transistor, only the sacrificial layers 15 may be disposed between the semiconductor substrate 11 and a film for fabricating the bottommost layer of the nanostructure layer and between adjacent films for fabricating layers of the nanostructure layer. In such case, the length of the inner sidewall 24 may be uniform throughout the thickness direction. Alternatively, besides the sacrificial layers, germanium-containing layers may be disposed between the semiconductor substrate 11 and the film for fabricating the bottommost layer of the nanostructure layer and between the adjacent films for fabricating layers of the nanostructure layer. In such case, details of the inner sidewall in the n-channel GAA transistor may refer to those of the inner sidewall in the p-channel GAA transistor.

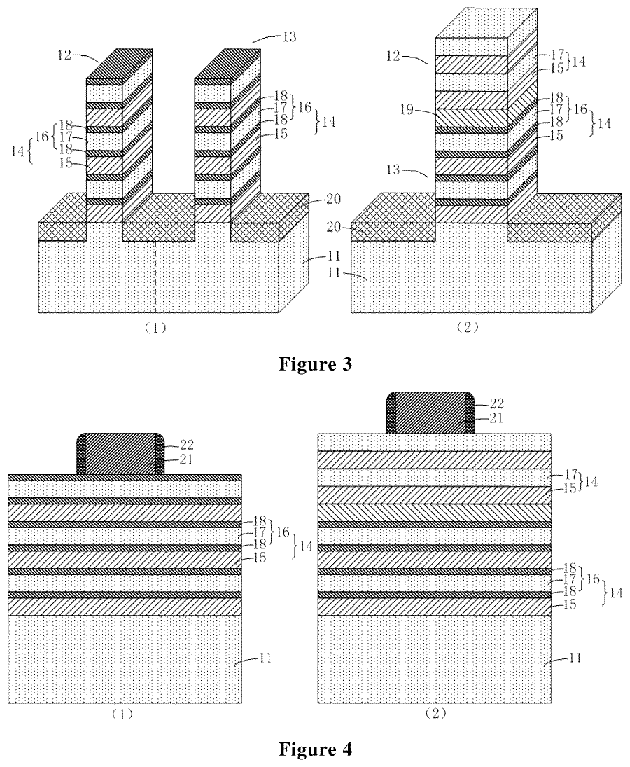

In an embodiment, the semiconductor device may further comprise shallow trench isolation and an interlayer dielectric layer. Reference is made to subfigures (1) and (2) of FIG. 3. The shallow trench isolation 20 may be formed in isolation region(s) of the semiconductor substrate 11 to isolate different active regions of the semiconductor substrate 11 and suppress leakage. Reference is made to subfigure (1) of FIG. 22, in which the n-channel GAA transistor and the p-channel GAA transistor are spaced apart along the direction parallel to the surface of the semiconductor substrate 11. The interlayer dielectric layer 28 may cover the n-channel GAA transistor, the p-channel GAA transistor, and the semiconductor substrate 11, and a top of the interlayer dielectric layer 28 is flush with the top of the gate stack structures 38 of the n-channel GAA transistor and the p-channel GAA transistor. Reference is made to subfigure (2) of FIG. 22, in which the n-channel GAA transistor and the p-channel GAA transistor are spaced apart along the thickness direction of the semiconductor substrate 11. The interlayer dielectric layer 28 may cover the semiconductor substrate 11 and an upper transistor between the n-channel GAA transistor and the p-channel GAA transistor. The top of the interlayer dielectric layer 28 is flush with the top of the gate stack structure 38 of the upper transistor. A material of the shallow trench isolation 20 and the interlayer dielectric layer 28 may be silicon oxide, silicon nitride, silicon oxynitride, or the like.

In the second aspect, a method for manufacturing a semiconductor device is provided according to an embodiment of the present disclosure. Hereinafter a process of the manufacturing is illustrated on a basis of stereoscopic or cross-sectional views in subfigures (1) and (2) of FIG. 1 through FIG. 22. The method for manufacturing the semiconductor device comprises following steps.

First, a first structure 32 and a second structure 33, which are spaced apart, are formed on a semiconductor substrate. Each of the first structure 32 and the second structure 33 comprises at least one suspended channel layer 30 and a gate sidewall 22, which is astride the at least one suspended channel layer 30 at two ends of the at least one suspended channel layer 30 along a length direction. The second structure 33 further comprises germanium-containing layers 31 located on two sides of each of the at least one suspended channel layer 30 along a thickness direction. A germanium content in the germanium-containing layers 31 is greater than germanium content in each of the at least one suspended channel layer 30.

The suspended channel layer(s) in the first structure are configured to fabricate the nanostructure layer(s) in the n-channel GAA transistor, and hence a quantity, a material, and a dimension of the suspended channel layer(s) in the first structure may be determined according to those of the nanostructure layer(s) in the n-channel GAA transistor. The suspended channel layer(s) in the second structure are configured to fabricate the nanostructure layer(s) in the p-channel GAA transistor. A portion of the suspended channel layer in the second structure located right beneath the gate sidewalls is configured to fabricate the connecting portion of the corresponding nanostructure layer in the p-channel GAA transistor, and the remaining portion of the suspended channel layer in the second structure is configured to fabricate the channel portion of the corresponding nanostructure layer in the p-channel GAA transistor. Hence, a quantity, a material, and a dimension of the suspended channel layer(s) in the second structure may be determined according to those of the nanostructure layer(s) in the p-channel GAA transistor. As an example, the nanostructure layers in the n-channel GAA transistor and the p-channel GAA transistor are identical in material except for existence or content of the germanium element, and in such case the suspended channel layers in the first structure and in the second structure may be made of the same material.

Then, a portion, of the germanium-containing layers 31 and the at least one suspended channel layer 30 in the second structure 33, exposed from a first mask layer is oxidized for segregation. During the oxidation, germanium atoms in the germanium-containing layer diffuse into a portion of the suspended channel layer(s), which is in the second structure and not located right beneath the gate sidewall 22. After the oxidation, the suspended channel layer(s) in the second structure forms the nanostructure layer(s) in the p-channel GAA transistor. Thereby, the germanium content and a thickness of the germanium-containing layers may be determined according to the germanium content to be achieved in the channel portion of the nanostructure layer(s) in the p-channel GAA transistor. The germanium content and the thickness of the germanium-containing layers are not specifically limited here.

Moreover, in practice, a relative position between the first structure and the second structure may vary depending on a relative position between the n-channel GAA transistor and the p-channel GAA transistor.

In an embodiment, the n-channel GAA transistor and the p-channel GAA transistor are spaced apart along the direction parallel to the surface of the semiconductor substrate. Reference is made to FIG. 18. In such case, the first structure 32 and the second structure 33 are spaced apart along the direction parallel to the surface of the semiconductor substrate 11. In another embodiment, the n-channel GAA transistor and the p-channel GAA transistor are spaced apart along the thickness direction. In such case, the first structure and the second structure are spaced apart along the thickness direction.

In addition, the first structure may comprise only the suspended channel layer(s) and the gate sidewall, and the second structure may comprise only the suspended channel layer, the germanium-containing layer(s), and the gate sidewall. Alternatively, the first structure and the second structure each may further comprise a source and a drain, which are located at two sides, respectively, of the suspended channel layer(s) along the length direction.

In an embodiment, forming the first structure and the second structure that are spaced apart on the semiconductor substrate may comprise following steps.

Reference is made to subfigures (1) and (2) of FIG. 3. At least a first fin structure 12 and a second fin structure 13, which are spaced apart, are formed on the semiconductor substrate 11. Each of the first fin structure 12 and the second fin structure 13 comprises at least one period of stacked layers 14. Each period of stacked layers 14 comprises a sacrificial layer 15 and a first semiconductor layer 16 that is located on the sacrificial layer 15. Each first semiconductor layer material layer in the second fin structure 13 comprises a second semiconductor layer 17 and germanium-containing material layers 18, and the germanium-containing material layers 18 are located on two sides, respectively, of the second semiconductor layer 17 along the thickness direction.

In practice, structures of the first fin and the second fin may vary depending on the relative position between the n-channel GAA transistor and the p-channel GAA transistor.

In an embodiment, the n-channel GAA transistor and the p-channel GAA transistor are spaced apart along the direction parallel to the surface of the semiconductor substrate. Reference is made to subfigure (1) of FIG. 3. In such case, the first fin structure 12 may be identical to the second fin structure 13. For example, the first semiconductor layer material layer in the first fin structure 12 also comprises the second semiconductor layer 17 and the germanium-containing material layers 18 that are located on two sides of the second semiconductor layer 17 along the thickness direction.

The case of the n-channel GAA transistor and the p-channel GAA transistor spaced apart along the direction parallel to the surface of the semiconductor substrate 11 is taken as an example. Reference is made to subfigure (1) of FIG. 1. Films stacked on the semiconductor substrate 11 are formed through epitaxy, and these films are configured to fabricate the sacrificial layers, the second semiconductor layers, and the germanium-containing material layers. Reference is then made to subfigure (1) of FIG. 2. These films and an upper part of the semiconductor substrate 11 are patterned through, for example, photolithography and etching, to form a first fin and a second fin on the semiconductor substrate 11. Reference is then made to subfigure (1) of FIG. 3. The shallow trench isolation 20 may be formed on the semiconductor substrate 11 through, for example, deposition and etching. A top surface of the shallow trench isolation 20 is lower than a bottom surface of the bottommost sacrificial layer 15. Portions of the first fin and the second fin that are exposed from the shallow trench isolation 20 serve as the first fin structure 12 and the second fin structure 13, respectively.

In another embodiment, the n-channel GAA transistor and the p-channel GAA transistor are spaced apart along thickness direction. In such case, the first fin structure and the second fin structure may be identical. Alternatively, as shown in subfigure (2) of FIG. 3, the first semiconductor layers in the first fin structure 12 may be identical in material but not comprise the germanium-containing material layers 18. In the latter case, it is not necessary to remove the germanium-containing material layers 18 from the second fin structure 13 when releasing the nanostructure layer(s) 35 in the n-channel GAA transistor. Hence, the n-channel GAA transistor can be fabricated with a simplified process and improved efficiency.

Reference is further made to subfigure (2) of FIG. 3. Moreover, when the n-channel GAA transistor and the p-channel GAA transistor are spaced apart along the thickness direction, forming at least the first fin structure 12 and the second fin structure 13 spaced apart on the semiconductor substrate 11 comprises a following step. At least the first fin structure 12, the second fin structure 13, and an isolation layer 19 between the first fin structure 12 and the second fin structure 13 are formed on the semiconductor substrate 11.

It is taken as an example that the first semiconductor layer in the first fin structure does not comprise the germanium-containing material layers and the p-channel GAA transistor is located beneath the n-channel GAA transistor. Reference is made to subfigure (2) of FIG. 1. Films stacked on the semiconductor substrate 11 are formed through epitaxy, and these films are configured to fabricate the sacrificial layer(s), the second semiconductor layers, and the germanium-containing material layers in the second fin structure. Then, a film for fabricating the isolation layer and then other films for fabricating the sacrificial layer(s) and the first semiconductor layer(s) in the first fin structure are formed on the topmost germanium-containing material layer. Reference is then made to subfigure (2) of FIG. 2. The above formed films and an upper part of the semiconductor substrate 11 are patterned through, for example, photolithography and etching, to form a fin protruding along the thickness direction is formed on the semiconductor substrate 11. Reference is then made to subfigure (1) of FIG. 3. The shallow trench isolation 20 is formed on the semiconductor substrate 11 through, for example, deposition and etching. A top surface of the shallow trench isolation 20 is lower than a bottom surface of the bottommost sacrificial layer 15. In a portion of the fin exposed from the shallow trench isolation 20, a lower part beneath the isolation layer 19 serves as the second fin structure 13, and an upper part located above the isolation layer 19 serves as the first fin structure 12.

Reference is made to subfigures (1) and (2) of FIG. 4. After the first fin structure 12 and the second fin structure 13 has been formed, a sacrificial gate 21 and a gate sidewall 22 that are astride the first fin structure 12 and the second fin structure 13 are formed through, for example, deposition and etching. The gate sidewall 22 is located at least on two sides of the sacrificial gate 21 along the length direction. A material of the sacrificial gate 21 may be polysilicon or another material which can be easily removed. A material of the gate sidewall 22 may refer to the foregoing description.

Reference is made to subfigures (1) and (2) of FIG. 5. At least the first fin structure 12 and the second fin structure 13 are removed through, for example, dry etching or wet etching, with masking of the sacrificial gate 21 and the gate sidewall 22.

Reference is made to subfigure (1) of FIG. 5, where the n-channel GAA transistor and the p-channel GAA transistor are spaced apart in the direction parallel to the surface of the semiconductor substrate 11. The first fin structure and the second fin structure each may be etched with masking of the respective sacrificial gate 21 and the respective gate sidewall 22. Reference is made to subfigure (2 of FIG. 5, where n-channel GAA transistor and the p-channel GAA transistor are spaced apart in the thickness direction. The first fin structure, the second fin structure, and the isolation layer 19 may be dry-etched or wet-etched under masking the sacrificial gate 21 and the gate sidewalls 22.

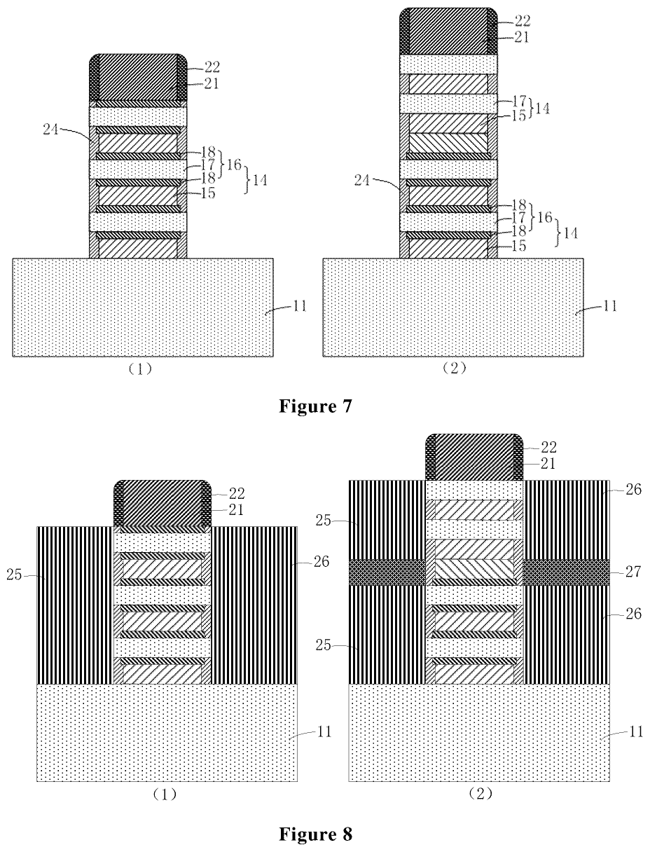

In an embodiment, the p-channel GAA transistor further comprises inner sidewalls 24. After the second fin structure has been etched but before a source and a drain of the p-channel GAA transistor are formed on two sides of the etched second fin structure along the length direction, the method further comprises a following step. Reference is made to subfigures (1) and (2) of FIG. 6. Along the length direction, edge regions (e.g., ends) at two sides of the remaining sacrificial layer(s) 15 in the etched second fin structure and edge regions (e.g., ends) at two sides of the remaining germanium-containing material layers 18 are removed through, for example, dry etching or wet etching, to form recesses 23. Reference is then made to subfigures (1) and (2) of FIG. 7. The inner sidewalls 24 filling the recesses are formed through, for example, deposition and etching.

In an embodiment, the n-channel GAA transistor further comprises inner sidewalls. After the first fin structure has been etched but before a source and a drain of the n-channel GAA transistor are formed on two sides of the etched first fin structure along the length direction, the method further comprises a following step. Reference is made to subfigures (1) and (2) of FIG. 6. Along the length direction, edge regions (e.g., ends) at two sides of the remaining sacrificial layer(s) 15 in the etched first fin structure are removed through, for example, dry etching or wet etching, to form recesses. In a case that the first semiconductor material layer 16 in the first fin structure comprises germanium-containing material layers 18, edge regions (e.g., ends) at two sides of the remaining germanium-containing material layers 18 are also etched in this step. Reference is then made to subfigures (1) and (2) of FIG. 7. The inner sidewalls filling the recesses are formed through, for example, deposition and etching.

Reference is then made to subfigures (1) and (2) of FIG. 8. The source 25 and the drain 26 of the n-channel GAA transistor are formed on two sides, respectively, of the etched first fin structure along the length direction. The source 25 and the drain 26 of the p-channel GAA transistor are formed on two sides, respectively, of the remaining portion of the second fin structure along the length direction.

In an embodiment, the n-channel GAA transistor and the p-channel GAA transistor are spaced apart in the direction parallel to the surface of the semiconductor substrate, and the source and the drain in each of the n-channel GAA transistor and the p-channel GAA transistor may be fabricated under a respective mask layer. For example, a third mask layer is first formed to shield the etched second fin structure, and then the source and the drain of the n-channel GAA transistor are formed through, for example, epitaxy. Afterwards, the third mask layer is removed, and a fourth mask layer is formed to shield the source and the drain of the n-channel GAA transistor. Then, the source and the drain of the p-channel GAA transistor is formed with masking of the fourth mask layer through, for example, epitaxy. Afterwards, the fourth mask layer is removed.

In another embodiment, the n-channel GAA transistor and the p-channel GAA transistor are spaced apart in the thickness direction, and a material layer for fabricating the source and the drain of a lower transistor between the n-channel GAA transistor and the p-channel GAA transistor is formed through, for example, epitaxy. Then, the material layer is etched back to form the source and drain of the lower transistor. Afterwards, a dielectric isolation layer is formed through, for example, deposition and etching. Then, the source and the drain of an upper transistor between the n-channel GAA transistor and the p-channel GAA transistor are formed through, for example, epitaxy.

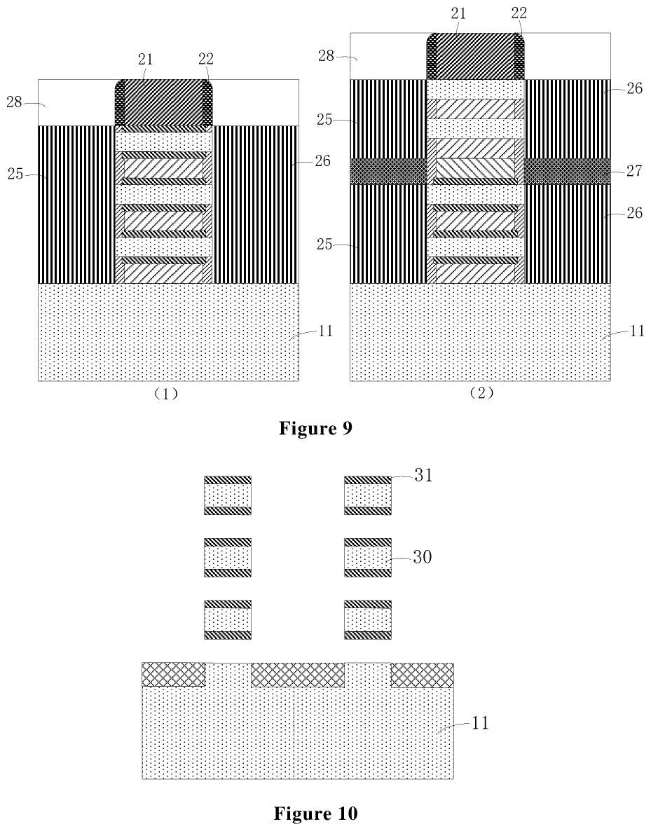

Reference is made to subfigures (1) and (2) of FIG. 9. An interlayer dielectric layer 28 may be formed through, for example, deposition and planarization. A thickness and a material of the interlayer dielectric layer 28 may refer to the foregoing description and are not repeated here.

Reference is then made to FIG. 10. At least the sacrificial gate and the remaining sacrificial layer(s) are removed. The remaining second semiconductor layer(s) form the suspended channel layer(s) 30, and the remaining germanium-containing material layers 18 form the germanium-containing layers 31.

In an embodiment, the n-channel GAA transistor and the p-channel GAA transistor are spaced apart in the direction parallel to the surface of the semiconductor substrate, and the sacrificial gate and the remaining sacrificial layer(s) shall be removed through dry etching or wet etching. Reference is made to FIGS. 12 and 16. The remaining germanium-containing material layers 18 in the first fin structure shall also be removed with masking of the second mask layer 29. The second mask layer 29 covers at least the remaining germanium-containing material layers 18 in the second fin structure.

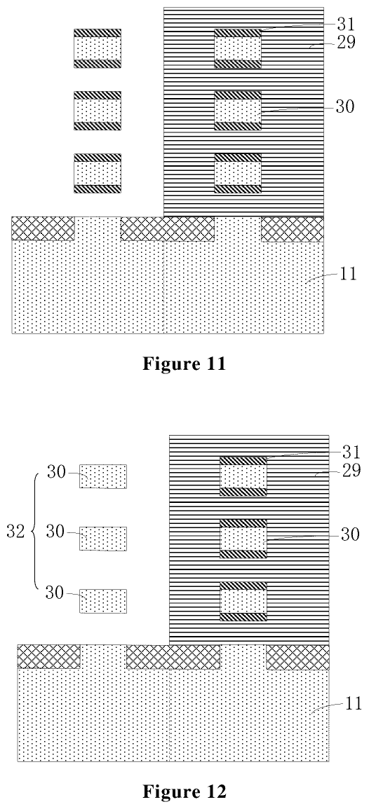

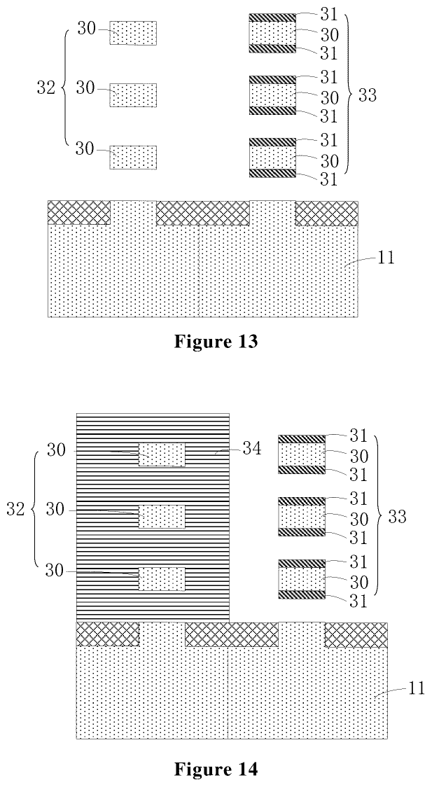

Reference is made to FIG. 10. In an embodiment, the sacrificial gates astride the first fin structure and the second fin structure, along with the remaining sacrificial layer(s), are removed through, for example, dry etching or wet etching. Reference is then made to FIGS. 11 and 12. The remaining germanium-containing material layers 18 in the first fin structure is removed with masking of the second mask layer 29 through, for example, dry etching or wet etching. Reference is then made to FIG. 13. The second mask layer is removed.

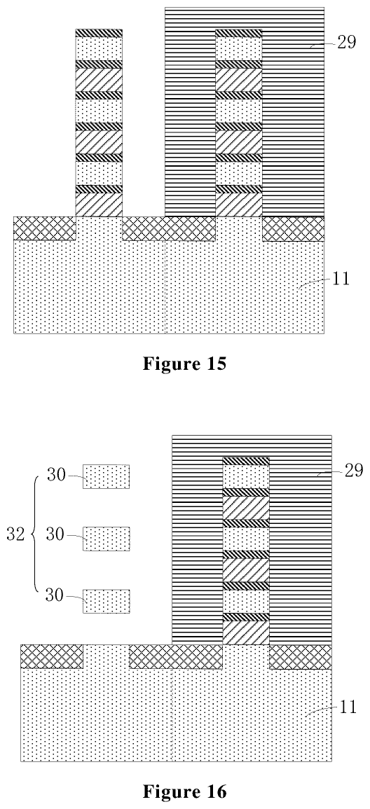

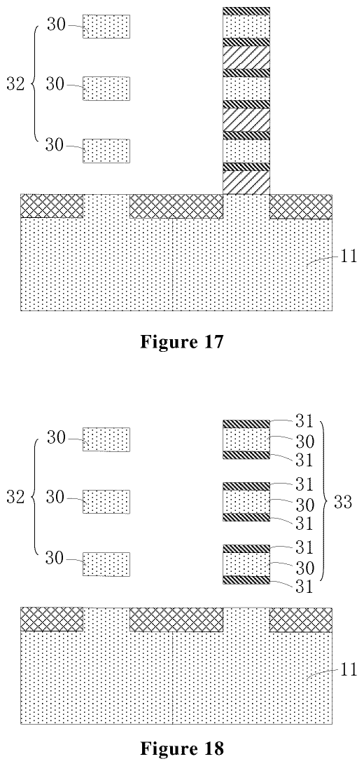

In another embodiment, the sacrificial gates astride the first fin structure and the second fin structure are removed through, for example, dry etching or wet etching. Reference is made to FIG. 15. The second mask layer 29 is formed to shield at least the remaining second fin structure. Reference is then made to FIG. 16. The remaining sacrificial layer(s) and the germanium-containing material layers in the first fin structure are removed with masking of the second mask layer 29. Reference is then made to FIG. 17. The second mask layer 29 is removed. Reference is then made to FIG. 18. The remaining sacrificial layer(s) in the second fin structure is removed.

In another embodiment, the n-channel GAA transistor and the p-channel GAA transistor are spaced apart in the thickness direction, and the sacrificial gates, the remaining sacrificial layer(s), and the remaining isolation layer may be removed through, for example, dry etching or wet etching.

Reference is made to FIG. 14. After the first structure and the second structure has been formed, a first mask layer 34 is formed through, for example, deposition and etching, to shield the first structure 32. A material of the first mask layer 34 may comprise a photoresist, spin-on carbon, or the like.

In an embodiment, the n-channel GAA transistor and the p-channel GAA transistor are spaced apart in the direction parallel to the surface of the semiconductor substrate, and the first mask layer may be formed through, for example, photolithography.

In another embodiment, the n-channel GAA transistor and the p-channel GAA transistor are spaced apart in the thickness direction. In a case that the n-channel GAA transistor is located beneath the p-channel GAA transistor, a mask material burying the suspended channel layer(s) in the first structure, the suspended channel layer(s) in the second structure, and the germanium-containing layers in the second structure may be formed through, for example, deposition. Then, the mask material is etched back through to expose the suspended channel layer(s) and the germanium-containing layers in the second structure, thereby obtaining the first mask layer. In a case that the n-channel GAA transistor is located above the p-channel GAA transistor, a fifth mask layer burying the suspended channel layer(s) and the germanium-containing layers in the second structure is formed in a same manner as forming the first mask layer in the foregoing case. Afterwards, the first mask layer burying the suspended channel layer(s) in the first structure is formed, and then the fifth mask layer is removed. In such case, a material of the fifth mask layer is different from a material of the first mask layer.

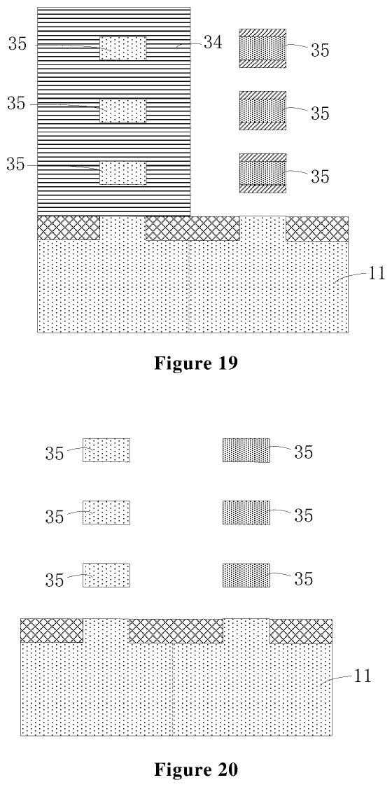

Reference is then made to FIG. 19. A portion, of the germanium-containing layers 31 and the suspended channel layer(s) of the second structure 33, exposed from the first mask layer 34 and the gate sidewall 22 is oxidized for segregation.

A condition of the oxidation may be determined according to an actual application scenario and is not specifically limited here. In an embodiment, the oxidation is performed under an oxygen-containing atmosphere under temperature ranging from 600° C. to 800° C. for a period ranging from 1 h to 6 h.

After the portion of the germanium-containing layers and the suspended channel layer(s) in the second structure is concentrated and oxidized, the remaining portion of the suspended channel layer(s) in the second structure becomes the nanostructure layer(s) in the p-channel GAA transistor.

Reference is made to subfigures (1) and (2) in FIGS. 20 to 22. After the oxidation for segregation, the n-channel GAA transistor is formed on a basis of the first structure 32, and the p-channel GAA transistor is formed on a basis of the second structure 33. The n-channel GAA transistor and the p-channel GAA transistor are spaced apart. Each of the n-channel GAA transistor and the p-channel GAA transistor comprises the active structure, and the active structure comprises the source 25, the drain 26, and at least one nanostructure layer 35 located between the source 25 and the drain 26. The p-channel GAA transistor further comprises the gate stack structure 38 and the gate sidewall 22. In the p-channel GAA transistor, the at least one nanostructure layer 35 comprises the channel portion 36 covered by the gate stack structure 38 and the connecting portion 37 covered by the gate sidewall 22. The germanium content in the channel portion 36 is greater than the germanium content in the connecting portion 37 and greater than the germanium content in the at least one nanostructure layer 35 in the n-channel GAA transistor.

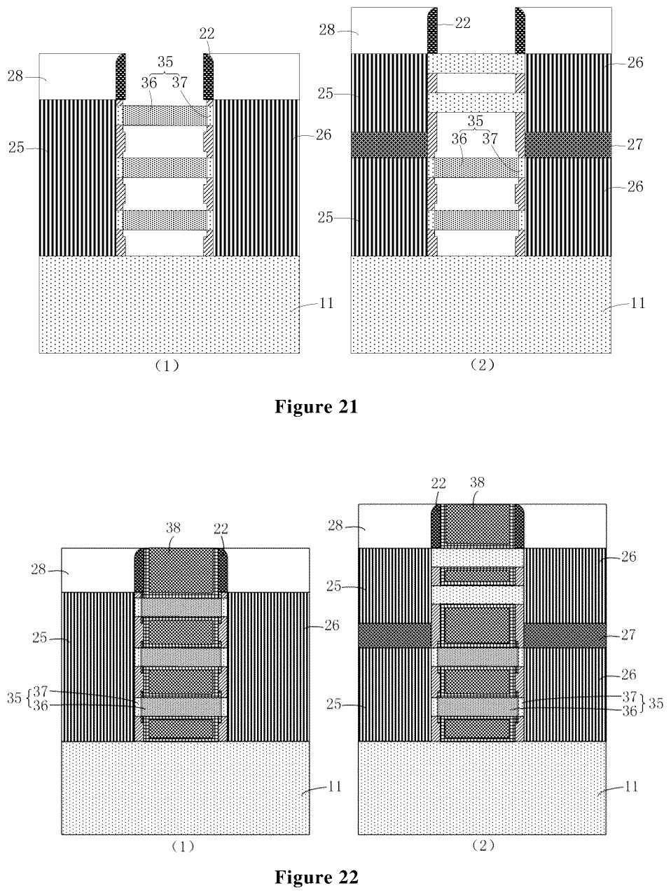

Reference is made to subfigures (1) and (2) of FIGS. 20 and 21. In an embodiment, the oxidized germanium-containing (previously) layers (e.g., silicon oxide layers), which is located on the nanostructure layer(s) 35 in the p-channel GAA transistor, and the first mask layer are removed through, for example, dry etching or wet etching. Reference is then made to subfigures (1) and (2) of FIG. 22. The gate stack structures 38 of the n-channel GAA transistor and the p-channel GAA transistor are formed.

The gate stack structure of the n-channel GAA transistor and the gate stack structure of the p-channel GAA transistor may be simultaneous formed or separately formed. An order of forming the the gate stack structures in the n-channel GAA transistor and the p-channel GAA transistor are not specifically limited here.

Beneficial effects of the method may refer to those of the semiconductor device in the first aspect and would not be repeated here.

Some technical details of the foregoing processing, such as patterning and etching may be omitted in the description. Those skilled in the art have the knowledge of various technical means for forming a layer, a region, or the like having a required shape. In addition, those skilled in the art may derive other embodiments form the above embodiments. Although described separately in the foregoing description, the embodiments of the present disclosure may be combined combination to achieve a technical advantage.

Hereinabove the embodiments of the present disclosure have been described. The embodiments are only illustrative and are not intended for limiting the scope of the present disclosure. The scope of the disclosure is defined by the appended claims and their equivalents. Those skilled in the art may make various substitutions and modifications without departing from the scope of the present disclosure, and these substitutions and modifications shall fall within the scope of the present disclosure.

1. A semiconductor device, comprising an n-channel GAA transistor and a p-channel GAA transistor, which are spaced apart, wherein:
each of the n-channel GAA transistor and the p-channel GAA transistor comprises a source, a drain, and at least one nanostructure layer located between the source and the drain;
the p-channel GAA transistor further comprises a gate stack structure and a gate sidewall;
in the p-channel GAA transistor, the at least one nanostructure layer comprises a channel portion that is covered by the gate stack structure and a connecting portion that is covered by the gate sidewall; and
germanium content in the channel portion is greater than germanium content in the connecting portion and is greater than germanium content in the at least one nanostructure layer of the n-channel GAA transistor.

2. The semiconductor device according to claim 1, wherein the germanium content in the channel portion is greater than or equal to 10% and less than or equal to 60%.

3. The semiconductor device according to claim 1, wherein a material of the channel portion is germanium silicon.

4. The semiconductor device according to claim 1, wherein the germanium content in the connecting portion and the germanium content in the at least one nanostructure layer of the n-channel GAA transistor are equal to zero.

5. The semiconductor device according to claim 1, wherein a material of the connecting portion is silicon.

6. The semiconductor device according to claim 1, wherein a material of the connecting portion is germanium silicon, and the germanium content in the connecting portion is less than 10%.

7. The semiconductor device according to claim 1, wherein a material of the at least one nanostructure layer of the n-channel GAA transistor is silicon.

8. The semiconductor device according to claim 1, wherein:
the p-channel GAA transistor comprises inner sidewalls, and the inner sidewalls are located between the source and the gate stack structure and between the drain and the gate stack structure in the p-channel GAA transistor;
a dimension of each of the inner sidewalls along a first direction is uniform throughout a second direction, or a dimension of a middle portion of each of the inner sidewalls along a first direction is larger than dimensions of ending portions of said inner wall along the first direction throughout a second direction; and
the first direction is a direction pointing from the source to the drain of the p-channel GAA transistor, the second direction is a perpendicular to the first direction, and the at least one nanostructure layer are sequentially arranged along the second direction when a quantity of the at least one nanostructure layer being greater than one.

9. The semiconductor device according to claim 1, further comprising a semiconductor substrate, wherein:
the n-channel GAA transistor and the p-channel GAA transistor are located on a surface of the semiconductor substrate and are spaced apart along a direction parallel to the surface.

10. The semiconductor device according to claim 1, further comprising a semiconductor substrate, wherein:
the n-channel GAA transistor and the p-channel GAA transistor are located on a surface of the semiconductor substrate and are spaced apart along a direction perpendicular to the surface.

11. A method for manufacturing a semiconductor device, comprising:
providing an n-channel GAA transistor and a p-channel GAA transistor, which are spaced apart, wherein:
each of the n-channel GAA transistor and the p-channel GAA transistor comprises a source, a drain, and at least one nanostructure layer located between the source and the drain;
the p-channel GAA transistor further comprises a gate stack structure and a gate sidewall;
in the p-channel GAA transistor, the at least one nanostructure layer comprises a channel portion that is covered by the gate stack structure and a connecting portion that is covered by the gate sidewall; and
germanium content in the channel portion is greater than germanium content in the connecting portion and is greater than germanium content in the at least one nanostructure layer of the n-channel GAA transistor.

12. The method according to claim 11, wherein providing the n-channel GAA transistor and the p-channel GAA transistor, which are spaced apart, comprises:
forming a first structure and a second structure, which are spaced apart, on a surface of a semiconductor substrate, wherein:
each of the first structure and the second structure comprises at least one suspended channel layer and a gate sidewall, and the gate sidewall is astride the at least one suspended channel layer at two ends of the at least one suspended channel layer along a first direction;
the second structure further comprises germanium-containing layers, which are located on two sides of each of the at least one suspended channel layer along a second direction; and
a germanium content in the germanium-containing layers is greater than germanium content in each of the at least one suspended channel layer; and
oxidizing a portion of the germanium-containing layers and the at least one suspended channel layer in the second structure to segregate germanium, wherein the portion is exposed from a first mask layer and the gate sidewall, and the first mask layer shields the first structure; and
forming, after the oxidizing, the n-channel GAA transistor and the p-channel GAA transistor based on the first structure and the second structure, respectively;
wherein the first direction is a direction pointing from the source to the drain, the second direction is a perpendicular to the surface of the semiconductor substrate.

13. The method according to claim 12, wherein the at least one suspended channel layer in the first structure and the at least one suspended channel layer are identical in material.

14. The method according to claim 12, wherein each of the first structure and the second structure comprises the source and the drain.

15. The method according to claim 12, wherein forming the first structure and the second structure, which are spaced apart, on the surface of the semiconductor substrate comprises:
forming a first fin structure and a second fin structure, which are spaced apart, on the semiconductor substrate, wherein:
each of the first fin structure and the second fin structure comprises at least one period of stacked layers;
each of the at least one period comprises a sacrificial layer and a first semiconductor layer located on the sacrificial layer; and
the first semiconductor layer material layer in the second fin structure comprises a second semiconductor layer and germanium-containing material layers located on two sides of the second semiconductor layer along the second direction;
forming a sacrificial gate and a gate sidewall on each of the first fin structure and the second fin structure, wherein the sacrificial gate and the gate sidewall are astride a corresponding one of the first fin structure and the second fin structure, and the gate sidewall is located on two sides of the sacrificial gate along the first direction;
etching the first fin structure and the second fin structure with masking of the sacrificial gate and the gate sidewall;
forming the source and the drain of the n-channel GAA transistor on two sides of the etched first fin structure along the first direction;
forming the source and the drain of the p-channel GAA transistor on two sides of the etched second fin structure along the first direction; and
removing the sacrificial gate and the sacrificial layer in the etched first fin structure and the etched second fin structure;
wherein the second semiconductor layer remained in the etched second fin structure forms a corresponding one of the at least one suspended channel layer in the second structure, and the germanium-containing material layers remained in the etched second fin structure forms form the germanium-containing layers in the second structure.

16. The method according to claim 15, wherein:
the n-channel GAA transistor and the p-channel GAA transistor are spaced apart along a direction parallel to the surface of the semiconductor substrate;
the first fin structure and the second fin structure are identical in structure, and the first semiconductor layer in the first fin structure comprises another second semiconductor layer and other germanium-containing material layers located on two sides of the another second semiconductor layer along the second direction; and
after removing the sacrificial layer in the etched first fin structure, and oxidizing the portion of the germanium-containing layers and the at least one suspended channel layer in the second structure to segregate germanium, the method further comprises:
removing the other germanium-containing material layers remaining in the etched first fin structure with masking of a second mask layer, wherein the second mask layer covers the germanium-containing material layers remaining in the etched the second fin structure.

17. The method according to claim 15, wherein:
the n-channel GAA transistor and the p-channel GAA transistor are spaced apart along a second direction;
forming the first fin structure and the second fin structure, which are spaced apart, on the semiconductor substrate comprises:
forming an isolation layer between the first fin structure and the second fin structure;
etching the first fin structure and the second fin structure with masking of the sacrificial gate and the gate sidewall comprises:
etching the isolation layer with masking of the sacrificial gate and the gate sidewalls; and
between forming the source and the drain of the n-channel GAA transistor on the two sides of the etched first fin structure along the first direction and forming the source and the drain of the p-channel GAA transistor on the two sides of the etched second fin structure along the first direction, the method further comprises:
forming a dielectric isolation layer that is configured to isolate the source and the drain of the n-channel GAA transistor from the source and the drain of the p-channel GAA transistor.

18. The method according to claim 15, wherein after etching the first fin structure and the second fin structure with masking of the sacrificial gate and the gate sidewall, and before forming the source and the drain of the p-channel GAA transistor on the two sides of the etched second fin structure along the first direction, the method further comprises:
etching the sacrificial layer and the germanium-containing material layers, which remain in the etched second fin structure, from two side surfaces of the etched second fin structure along the first direction to from recesses; and
forming inner sidewalls in the recesses.
